(19) United States
(12) Patent Application Publication
(10) Pub. No.: US 2015/0153400 A1
(43) Pub. Date: Jun. 4, 2015

(54) DETECTION SYSTEM AND METHOD OF DISCONNECTION OF MOTOR POWER CABLE AND MOTOR CONTROL METHOD

(71) Applicants: Taeil Yoo, Anyang-si (KR); Gu Bae Kang, Yongin-si (KR)

(72) Inventors: Taeil Yoo, Anyang-si (KR); Gu Bae Kang, Yongin-si (KR)

(73) Assignee: HYUNDAI MOTOR COMPANY, Seoul (KR)

(21) Appl. No.: 14/095,554

(22) Filed: Dec. 3, 2013

(51) Int. Cl. G01R 31/02; H02P 21/00

(52) U.S. Cl. CPC G01R 31/021; H02P 21/0096

(57) ABSTRACT

A system and method of detecting disconnection of a power cable of a motor that includes measuring, by a controller, a plurality of phase currents supplied to a motor via a power cable from an inverter and transforming the plurality of phase currents to a stationary reference frame to obtain a first axis current of the synchronous reference frame and a second axis current of the synchronous reference frame. In addition, the method includes calculating, by the controller, a cable open factor using the first axis current of the stationary reference frame and the second axis current of the stationary reference frame and detecting disconnection of the power cable using the cable open factor.

### CROSS-REFERENCE TO RELATED APPLICATION

This application claims priority to and the benefit of Korean Patent Application No. 10-2012-0146801 filed in the Korean Intellectual Property Office on Dec. 14, 2012, the entire contents of which are incorporated herein by reference.

### BACKGROUND

(a) Field of the Invention

The present invention relates to a detection method of disconnection of a motor power cable, and a motor control method, and more particularly, to a method of detecting disconnection of a power cable that connects a motor and an inverter in a vehicle, and a motor control method using the detection system.

(b) Description of the Related Art

In general, a permanent magnet type motor is applied to an electric vehicle, a hybrid vehicle, a fuel cell vehicle, and the like, as a driving means. The inverter may convert a DC voltage into three-phase AC voltages (u-phase, v-phase, and w-phase) to provide the converted AC voltages to a motor via a power cable, and a motor controller may be configured to operate the inverter via a pulse width modulation (PWM).

However, when disconnection, short, removal, or the like is generated in the power cable that connects the inverter and the motor, an overcurrent and overvoltage are generated, or a fatal problem, such as the generation of the overcurrent and the overvoltage or resultant damage to the inverter may occur, and the motor may not be smoothly driven.

Accordingly, when a situation, such as disconnection, short, and removal, of the power cable is generated, the motor controller must perform a series of functions for immediately detecting the situation, protecting a system, and cutting off power of the system to prevent other problems from occurring.

A method of detecting disconnection of a motor power cable in the related art will be described below. A phase current of the power cable, in which disconnection is generated, has a current value of 0 regardless of inverter operation, causing phase currents of the remaining two power cables to have a substantial difference compared to a current command value. When the current difference is maintained for a predetermined time or more, disconnection of the power cable is detected. In the actual implementation, when a sum of three-phase currents is maintained for a predetermined time (e.g., 30 msec) while having the aforementioned current difference within a predetermined range, not 0, (e.g., within |10A|) considering a measurement error of a current sensor is detected as a disconnection. In particular, since the sum of the three-phase currents is limited to a predetermined range, not 0, a separate condition (e.g., a peak of the phase current is about 50 A or more) may be further set to determine whether the power cable is in a normal state (e.g., no failure has occurred) or a failure state.

As described above, various conditions are set in the related art, and thus the disconnection may not be detected even though the power cable is actually disconnected. Further, when the phase current is increased to a level of an overcurrent or greater within a predetermined time, it may be difficult to detect the disconnection.

The above information disclosed in this section is only for enhancement of understanding of the background of the invention and therefore it may contain information that does not form the prior art that is already known in this country to a person of ordinary skill in the art.

### SUMMARY

The present invention provides a method of detecting disconnection of a motor power cable, having advantages of accurately detecting generation of disconnection of the power cable, and a motor control method using the detection of the motor power cable disconnection.

An exemplary embodiment of the present invention provides a method of detecting disconnection of a motor power cable, including: measuring a plurality of phase currents supplied to a motor via a power cable from an inverter; transforming the plurality of phase currents to a stationary reference frame (stationary coordinate system) to obtain a first axis current of the stationary reference frame and a second axis current of the stationary reference frame; calculating a cable open factor using the first axis current of the stationary reference frame and the second axis current of the stationary reference frame; and detecting disconnection of the power cable by the cable open factor.

The cable open factor may be defined by an equation below,

$$K = \frac{Idss}{Iqss}$$

wherein, K is the cable open factor, Idss is the first axis current of the stationary reference frame, and Iqss is the second axis current of the stationary reference frame.

The power cable may include a first power cable, a second power cable, and a third power cable, and when the cable open factor is included in an open factor range of the first power cable, disconnection of the first power cable may be detected, when the cable open factor is included in an open factor range of the second power cable, disconnection of the second power cable may be detected, and when the cable open factor is included in an open factor range of the third power cable, disconnection of the third power cable may be detected.

Another exemplary embodiment of the present invention provides a method of controlling a motor, including: measuring a plurality of phase currents supplied to a motor via a power cable from an inverter; transforming a plurality of phase currents to a stationary reference frame and then transforming the transformed currents to a synchronous reference frame; detecting disconnection of the power cable; calculating a pulse width modulation (PWM) duty using the current of the synchronous reference frame; and operating the inverter based on the PWM duty.

When the phase current is transformed to the stationary reference frame, the first axis current of the stationary reference frame and the second axis current of the stationary reference frame may be generated. When the disconnection of the power cable is detected, a cable open factor may be calculated using the first axis current of the stationary reference frame and the second axis current of the stationary reference frame, and the disconnection of the power cable may be detected using the cable open factor.

The cable open factor may be defined by an equation below,

$$K = \frac{Idss}{Iqss}$$

wherein, K is the cable open factor, Idss is the first axis current of the stationary reference frame, and Iqss is the second axis current of the stationary reference frame.

The power cable may include a first power cable, a second power cable, and a third power cable, and when the cable open factor is included in an open factor range of the first power cable, disconnection of the first power cable may be detected, when the cable open factor is included in an open factor range of the second power cable, disconnection of the second power cable may be detected, and when the cable open factor is included in an open factor range of the third power cable, disconnection of the third power cable may be detected.

The detecting of the disconnection of the power cable may be performed before the calculating of the PWM duty, or the detecting of the disconnection of the power cable may be performed in parallel with at least one of the calculating of the PWM duty and the operating of the inverter. After the detecting of the power cable disconnection, a subsequent logic necessary after the disconnection may be performed.

According to the present exemplary embodiments, whether the power cable is disconnected may be detected using only one cable open factor K having high reliability. Accordingly, it may be possible to easily, accurately, and rapidly detect whether the power cable is disconnected. Further, when the disconnection of the power cable is detected, it may be possible to prevent a secondary accident due to the disconnection of the power cable by executing a subsequent logic corresponding to the disconnection.

### BRIEF DESCRIPTION OF THE DRAWINGS

FIG. 1 is an exemplary flowchart illustrating a motor control method including a method of detecting disconnection of a motor power cable according to an exemplary embodiment of the present invention;

FIGS. 2A to 2C are exemplary graphs illustrating a current, a cable open factor K, and whether w-phase disconnection is detected in the w-phase disconnection according to an exemplary embodiment of the present invention;

FIGS. 3A to 3C are exemplary graphs illustrating a current, a cable open factor K, and whether v-phase disconnection is detected the v-phase disconnection according to an exemplary embodiment of the present invention;

FIGS. 4A to 4C are exemplary graphs illustrating a current, a cable open factor K, and whether u-phase disconnection is detected in the u-phase disconnection according to an exemplary embodiment of the present invention;

FIG. 5 is an exemplary flowchart illustrating a motor control method according to another exemplary embodiment of the present invention; and

FIG. 6 is an exemplary flowchart illustrating a motor control method according to yet another exemplary embodiment of the present invention.

### DETAILED DESCRIPTION

It is understood that the term “vehicle” or “vehicular” or other similar term as used herein is inclusive of motor vehicles in general such as passenger automobiles including sports utility vehicles (SUV), buses, trucks, various commercial vehicles, watercraft including a variety of boats and ships, aircraft, and the like, and includes hybrid vehicles, electric vehicles, plug-in hybrid electric vehicles, fuel cell vehicles and other alternative fuel vehicles (e.g. fuels derived from resources other than petroleum). As referred to herein, a hybrid vehicle is a vehicle that has two or more sources of power, for example both gasoline-powered and electric-powered vehicles.

Although exemplary embodiment is described as using a plurality of units to perform the exemplary process, it is understood that the exemplary processes may also be performed by one or plurality of modules. Additionally, it is understood that the term controller/control unit refers to a hardware device that includes a memory and a processor. The memory is configured to store the modules and the processor is specifically configured to execute said modules to perform one or more processes which are described further below.

Furthermore, control logic of the present invention may be embodied as non-transitory computer readable media on a computer readable medium containing executable program instructions executed by a processor, controller or the like. Examples of the computer readable mediums include, but are not limited to, ROM, RAM, compact disc (CD)-ROMs, magnetic tapes, floppy disks, flash drives, smart cards and optical data storage devices. The computer readable recording medium can also be distributed in network coupled computer systems so that the computer readable media is stored and executed in a distributed fashion, e.g., by a telematics server or a Controller Area Network (CAN).

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items.

Unless specifically stated or obvious from context, as used herein, the term “about” is understood as within a range of normal tolerance in the art, for example within 2 standard deviations of the mean. “About” can be understood as within 10%, 9%, 8%, 7%, 6%, 5%, 4%, 3%, 2%, 1%, 0.5%, 0.1%, 0.05%, or 0.01% of the stated value. Unless otherwise clear from the context, all numerical values provided herein are modified by the term “about.”

Hereinafter, an apparatus and a method of detecting disconnection of a motor power cable according to an exemplary embodiment of the present invention will be described in detail with reference to the accompanying drawings. However, the present invention is not limited to the exemplary embodiment, and may be modified in various forms.

A method of detecting disconnection of a motor power cable according to an exemplary embodiment of the present invention (hereinafter, referred to as a “disconnection detecting method”) may detect disconnection of the power cable using a cable open factor K. The method will be described in more detail below.

In the present exemplary embodiment, a cable open factor K may be calculated using a current, which is coordinate-transformed when a plurality of currents (e.g., three-phase currents) is coordinate-transformed in the motor control method. For example, the motor control method using a current regulator of a synchronous reference frame will be described first, and then a method of calculating a cable open factor K using the current, which is coordinate-transformed in the motor control method, and a disconnection detecting method using the same will be described.

In the motor control method, three-phase currents (a u-phase current Iu, a v-phase current Iv, and a w-phase current Iw) are coordinate-transformed using three or two current sensors. Specifically, a current may be measured by installing the current sensor within each of three-phase power cables. Otherwise, the two currents may be measured by installing current sensors in only two power cables, and the current of the power cable, in which the current sensor is not positioned, may be measured using a rule that a sum of values of the instantaneous three-phase currents is 0. Further, the three-phase currents may be transformed to a stationary reference frame by first coordinate transformation, and the three-phase currents transformed to the stationary reference frame may be transformed to a synchronous reference frame synchronized with a rotating magnetic field velocity by secondary coordinate transformation.

In the first coordinate transformation, the three-phase currents Iu, Iv, and Iw may be transformed to the stationary reference frame using Equations 1 and 2, to obtain a first axis current of the stationary reference frame (e.g., a d-axis current Idss of the stationary reference frame) and a second axis current of the stationary reference frame (e.g., a q-axis current Iqss of the stationary reference frame).

$$\begin{matrix}Idss = \frac{2}{3} Iu - \frac{1}{3} Iv - \frac{1}{3} Iw & ( Equation 1 ) \\ Iqss = \frac{1}{\sqrt{3}} Iv - \frac{1}{\sqrt{3}} Iw & ( Equation 2 )\end{matrix}$$

Further, in the secondary coordinate transformation, the current transformed to the stationary reference frame may be transformed to a synchronous reference frame using Equations 3 and 4 to obtain a d-axis current Idsr of the synchronous reference frame and a q-axis current Iqsr of the synchronous reference frame.

Idsr=cos θ·Idss+sin θ·Iqss (Equation 3)

Iqsr=−sin θ·Idss+cos θ19 Iqss (Equation 4)

The d-axis current Idsr of the synchronous reference frame and the synchronous reference frame q-axis current Iqsr may be input in a motor controller. A current regulator may be configured to compare a target d-axis current Idsr* of the synchronous reference frame and a target q-axis current Idsr* of the synchronous reference frame based on a load condition of the motor, with the actually measured d-axis current Idsr and q-axis current Iqsr of the synchronous reference frame, respectively, to output a target d-axis voltage Vdrs* and a target q-axis voltage Vqsr*. The motor may be controlled using the target d-axis voltage Vdrs* and the target q-axis voltage Vqsr*.

In the present exemplary embodiment, a cable open factor K may be calculated using the d-axis current Idss of the synchronous reference frame and the q-axis current Iqss of the synchronous reference frame obtained by the first coordinate transformation in the aforementioned motor control method. A method of calculating the cable open factor K, and a method of detecting disconnection of the power cable using the same will be described below.

The cable open factor K may be defined as Equation 5 below,

$$K = \frac{Idss}{Iqss} \qquad ( Equation 5 )$$

When the power cable of one phase among the power cables of the three phases of the motor is disconnected, the current may have a waveform different from waveforms of the three-phase currents in a normal state (e.g., when no failure has occurred).

A route through which a current may flow may be blocked in the disconnected power cable among the three power cables, to converge the current of the disconnected power cable to zero (0). When the current is measured via the current sensor, a zero-current Izero may be detected in the disconnected phase. The zero current Izero theoretically needs to have a value of 0, but a measurement error value of the zero-current, not the value of 0, may be detected by a measurement error of the current sensor, an error of an output detection circuit, and the like.

When the current measured in the one-phase power cable among two non-disconnected power cables is referred to as a first current Iopen, a second current (−Iopen+Iub) obtained by adding a current −Iopen having an opposite symbol to that of the first AM 259473551 current Iopen and an unbalanced current Iub is measured in the other non-disconnected power cable. Since the three-phase power cables have current balance, a sum of the phase current of the three power cables may be 0. Accordingly, the unbalanced current Iub may be 0. However, the current balance may not be achieved, and the unbalanced current Iub may have a value other than 0, due to the measurement error of the current sensor, an error of the detection circuit, current-flowing other than the three-phase power cables, and the like. Similarly, when any power cable is disconnected among the three power cables, a similar error may occur despite any phase among the non-disconnected power cables of the two phases being defined as the first current Iopen.

When the power cable of one phase is disconnected among the power cables of the three phases, the values of the three-phase currents Iu, Iv, and Iw, the d-axis current Idss of the synchronous reference frame and the q-axis current Iqss of the synchronous reference frame obtained by transforming the three phase currents Iu, Iv, and Iw into the stationary reference frame, and the cable open factor K calculated by Equation 5 are represented in Table 1.

TABLE 1

| | u-phase disconnection | v-phase disconnection | w-phase disconnection |
|---|---|---|---|
| Iu | Izero | Iopen | Iopen |
| Iv | Iopen | Izero | (−Iopen + Iub) |
| Iw | (−Iopen + Iub) | (−Iopen + Iub) | Izero |
| Idss | $\begin{matrix}Idss = \frac{2}{3} Izero - \frac{1}{3} Iopen - \frac{1}{3} ( - Iopen + Iub ) \\ = \frac{1}{3} ( 2 \cdot Izero - Iub )\end{matrix}$ | $\begin{matrix}Idss = \frac{2}{3} Iopen - \frac{1}{3} Izero - \frac{1}{3} ( - Iopen + Iub ) \\ = \frac{1}{3} ( 3 \cdot Iopen - Izero - Iub )\end{matrix}$ | $\begin{matrix}Idss = \frac{2}{3} Iopen - \frac{1}{3} ( - Iopen + Iub ) - \frac{1}{3} Izero \\ = \frac{1}{3} ( 3 \cdot Iopen - Izero - Iub )\end{matrix}$ |
| Iqss | $\begin{matrix}Iqss = \frac{1}{\sqrt{3}} Iopen - \frac{1}{\sqrt{3}} ( - Iopen + Iub ) \\ = \frac{1}{\sqrt{3}} ( 2 \cdot Iopen - Iub )\end{matrix}$ | $\begin{matrix}Iqss = \frac{1}{\sqrt{3}} Izero - \frac{1}{\sqrt{3}} ( - Iopen + Iub ) \\ = \frac{1}{\sqrt{3}} ( Izero + Iopen - Iub )\end{matrix}$ | $\begin{matrix}Iqss = \frac{1}{\sqrt{3}} ( - Iopen + Iub ) - \frac{1}{\sqrt{3}} Izero \\ = \frac{- 1}{\sqrt{3}} ( Iopen - Iub + Izero )\end{matrix}$ |
| K | $\frac{1}{\sqrt{3}} \cdot \frac{2 \cdot Izero - Iub}{2 \cdot Iopen - Iub}$ | $\frac{1}{\sqrt{3}} \cdot \frac{3 \cdot Iopen}{Iopen + Izero - Iub} - \frac{1}{\sqrt{3}} \cdot \\ \frac{Izero + Iub}{Iopen + Izero - Iub}$ | $- \sqrt{3} \cdot \frac{Iopen}{Iopen - Iub + Izero} - \frac{1}{\sqrt{3}} \cdot \\ \frac{Izero + Iub}{Iopen - Iub + Izero}$ |

In particular, when the value of the first current Iopen is larger than an absolute value of the zero current Izero and the current value of the unbalanced current Iub, the values of the cable open factors K are represented in Table 2 below.

TABLE 2

| | u-phase | v-phase | w-phase |
|---|---|---|---|
| | disconnection | disconnection | disconnection |
| K | ≅ 0 + ξ | ≅ \sqrt{3} + ξ | ≅ −\sqrt{3} + ξ |

As shown in Table 2, when the power cable of the one phase is disconnected among the power cables of the three phases, the value of the cable open factor K is different based on a type of the disconnected phase. In other words, the cable open factor K may be about 0 in the u-phase disconnection, the cable open factor K may be about \sqrt{3} in the v-phase disconnection, and the cable open factor K may be about \sqrt{−3} in the w-phase disconnection. As described above, the cable open factor K may have a different value based on the disconnection of each phase, and thus, the cable open factor K may be a reference for determining whether the power cable is disconnected.

Accordingly, in the present exemplary embodiment, a range and a time based on which a disconnection of the power cable is disconnected may be set, and when the cable open factor K is held for a predetermined time within the range, that the disconnection of the power cable may be detected. In other words, when the cable open factor K is held with a value between a minimum u-phase cable open factor Ku_min and a maximum u-phase cable open factor Ku_max for a u-phase holding time Tu_hold, a disconnection of the u-phase may be detected. When the cable open factor K is held with a value between a minimum v-phase cable open factor Kv_min and a maximum v-phase cable open factor Kv_max for a v-phase holding time Tv_hold, the disconnection of the v-phase may be detected. Further, when the cable open factor K is held with a value between a minimum w-phase cable open factor Kw_min and a maximum w-phase cable open factor Kw_max for a w-phase holding time Tw_hold, the disconnection of the w-phase may be detected.

Specific values of the minimum u-phase cable open factor Ku_min, the maximum u-phase cable open factor Ku_max, the minimum v-phase cable open factor Kv_min, the maximum v-phase cable open factor Kv_max, the minimum w-phase cable open factor Kw_min, the maximum w-phase cable open factor Kw_max, the u-phase holding time Tu_hold, the v-phase holding time Tv_hold, and the w-phase holding time Tw_hold may be changed based on a degree, by which the respective measurement errors, the error of the detection circuit, current-flowing other than the three-phase power cables, and the like which are reflected to set the open factor range.

As described above, the cable open factor K is about 0 in the u-phase disconnection, the cable open factor K is about \sqrt{3} in the v-phase disconnection, and the cable open factor K is about \sqrt{−3} in the w-phase disconnection.

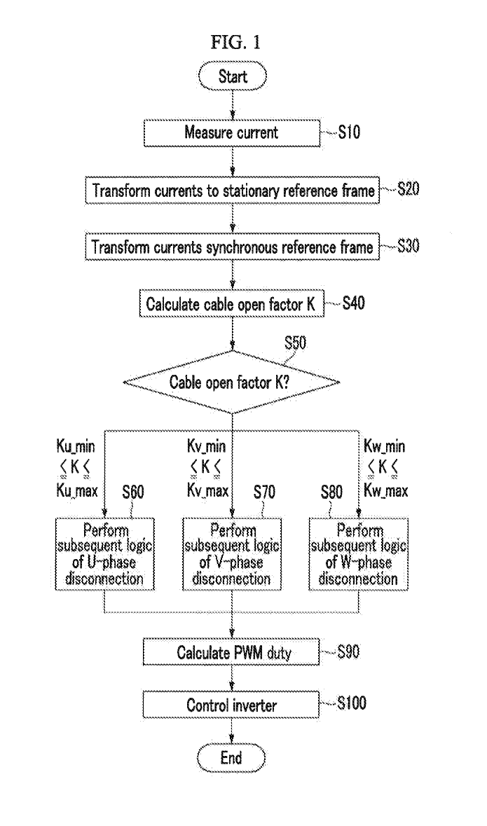

The aforementioned disconnection detecting method and motor control method will be described in more detail with reference to FIG. 1. FIG. 1 is an exemplary flowchart illustrating the motor control method including the disconnection detecting method of the motor power cable according to an exemplary embodiment of the present invention.

In the motor control method of the present exemplary embodiment, as illustrated in FIG. 1, the u-phase current Iu, the v-phase current Iv, and the w-phase current Iw may be measured (S10). The u-phase current Iu, the v-phase current Iv, and the w-phase current Iw may be measured using two current sensors or three current sensors.

Next, the u-phase current Iu, the v-phase current Iv, and the w-phase current Iw may be transformed to the stationary reference frame (S20), and then may be transformed to the synchronous reference frame (S30). Further, the cable open factor K may be calculated using the d-axis current Idss of the synchronous reference frame and the q-axis current Iqss of the synchronous reference frame, which are transformed to the stationary reference frame (S40). The disconnection of the power cables of the u-phase, the v-phase, and the w-phase may be detected based on the cable open factor K (S50), and necessary processing may be performed according to the detection (S60). In other words, when the cable open factor K is held with a value between the minimum u-phase cable open factor Ku_min and the maximum u-phase cable open factor Ku_max for the u-phase holding time Tu_hold, the disconnection of the u-phase may be detected, and when the u-phase is disconnected, a subsequent logic may be performed (S60).

Additionally, when the cable open factor K is held with a value between the minimum v-phase cable open factor Ku_min and the maximum v-phase cable open factor Kv_max for the v-phase holding time Tv_hold, the disconnection of the v-phase may be detected, and when the v-phase is disconnected, a subsequent logic may be performed (S70). When the cable open factor K is held with a value between the minimum w-phase cable open factor Kw_min and the maximum w-phase cable open factor Kw_max for the w-phase holding time Tw_hold, the disconnection of w-phase may be detected, and when the w-phase is disconnected, a subsequent logic may be performed (S80). Next, a PWM duty may be calculated by pulse width modulation (PWM) (S90). Subsequently, the inverter may be operated based on the PWM duty (S100).

In the present exemplary embodiment, the disconnection of the power cable may be detected using only one cable open factor K having high reliability. Accordingly, it may be possible to solve the problem in the related art of not detecting that the power cable is not disconnected even when only one detection condition is omitted from various detection conditions. Further, it may be possible to solve the problem in the related art of not detecting the disconnection even when the phase current is increased to a level of overcurrent or higher within a detection time. As described above, in the present exemplary embodiment, it may be possible to easily, accurately, and rapidly detect whether the power cable is disconnected using the cable open factor K. When the disconnection of the power cable is detected, it may be possible to prevent a secondary accident due to the connection of the power cable by executing a subsequent logic corresponding to the detection of the disconnection.

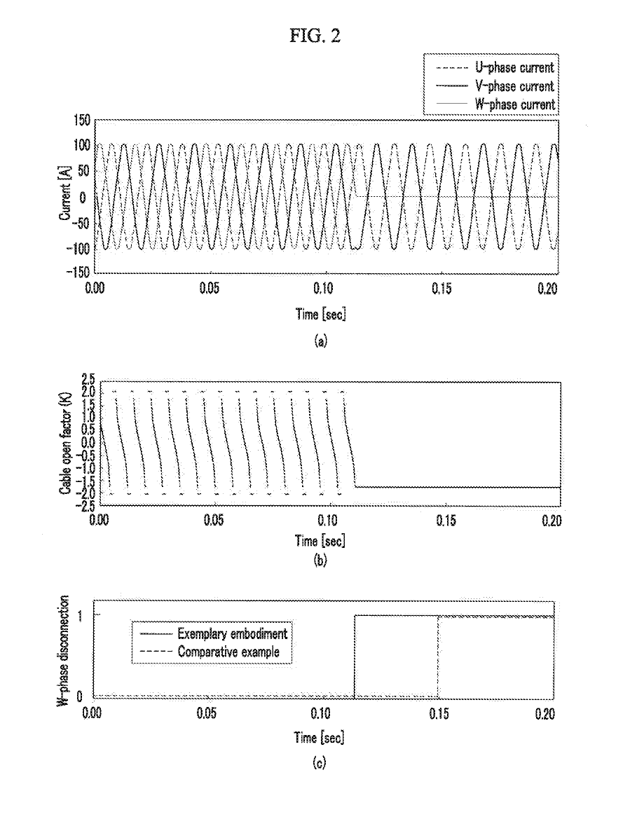

A result of detecting the w-phase disconnection, the v-phase disconnection, and the u-phase disconnection according to the disconnection detecting method according to the exemplary embodiment will be described with reference to FIGS. 2 to 4.

FIGS. 2A to 2C are exemplary graphs illustrating a current, the cable open factor K, and whether the w-phase disconnection is detected in the w-phase disconnection. When the w-phase current is 0 at about 0.10 second as illustrated in FIG. 2A, the cable open factor K may have a value between approximately −1.7 and −1.8 as illustrated in FIG. 2B. Then, in the present exemplary embodiment, it may be possible to immediately detect the w-phase disconnection as illustrated in FIG. 2C. In the meantime, in a Comparative Example, it can be seen that it may be possible to detect the w-phase disconnection only when the current difference is maintained for a predetermined time (e.g., about 0.03 sec).

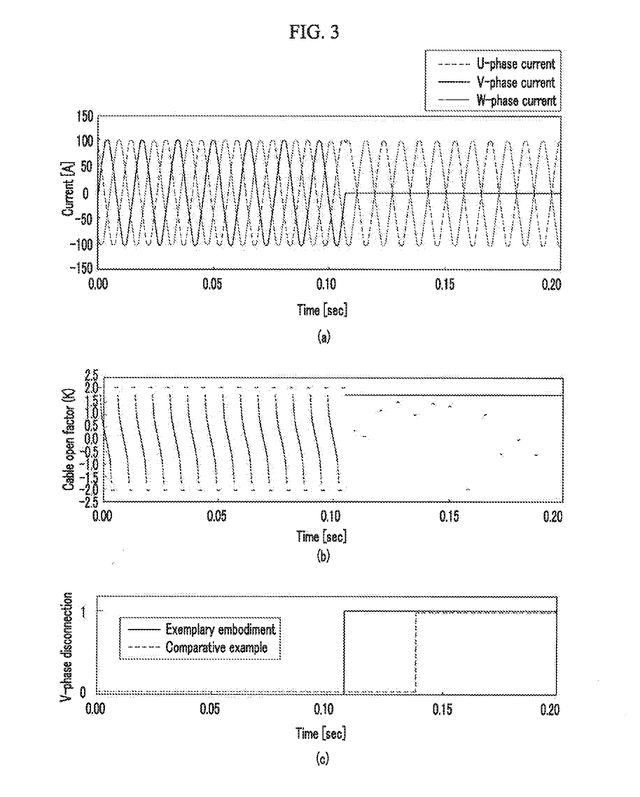

FIGS. 3A to 3C are exemplary graphs illustrating a current, the cable open factor K, and whether the v-phase disconnection is detected in the v-phase disconnection. When the v-phase current is 0 at about 0.10 second as illustrated in FIG. 3A, the cable open factor K may have a value between approximately 1.7 and 1.8 as illustrated in FIG. 3B. Then, in the present exemplary embodiment, it may be possible to immediately detect the v-phase disconnection as illustrated in FIG. 3C. In the meantime, in the Comparative Example, it can be seen that it may be possible to detect the v-phase disconnection only when the current difference is maintained for a predetermined time (e.g., about 0.03 sec).

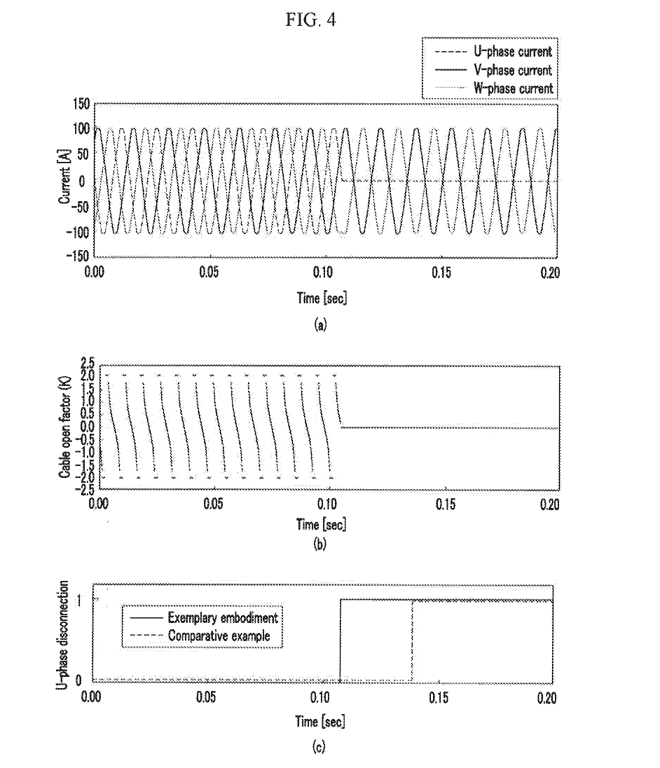

FIGS. 4A to 4C are exemplary graphs illustrating a current, the cable open factor K, and whether the u-phase disconnection is detected in the u-phase disconnection. When the u-phase current is 0 at about 0.10 second as illustrated in FIG. 4A, the cable open factor K may have a value of about 0 as illustrated in FIG. 4B. Then, in the present exemplary embodiment, it may be possible to immediately detect the u-phase disconnection as illustrated in FIG. 4C. In the meantime, in the Comparative Example, it can be seen that it may be possible to detect the u-phase disconnection only when the current difference is maintained for a predetermined time (about 0.03 see).

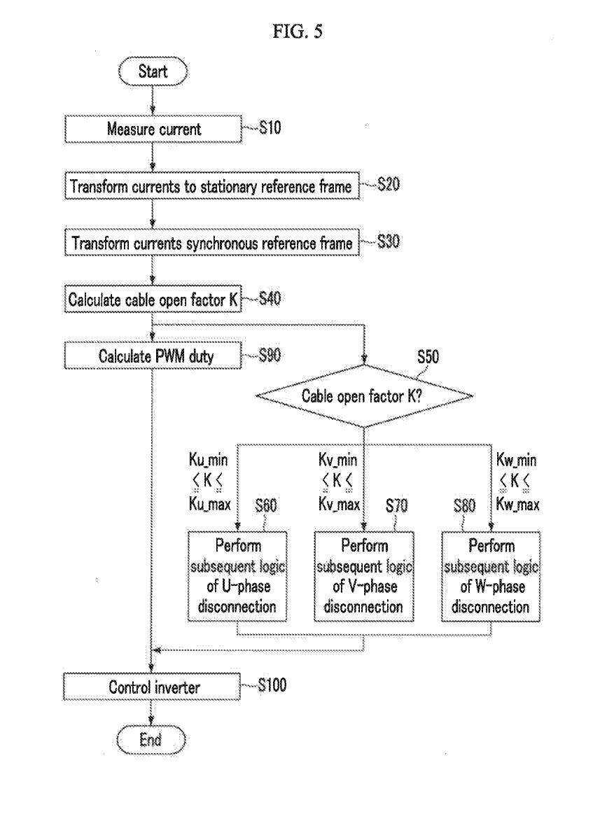

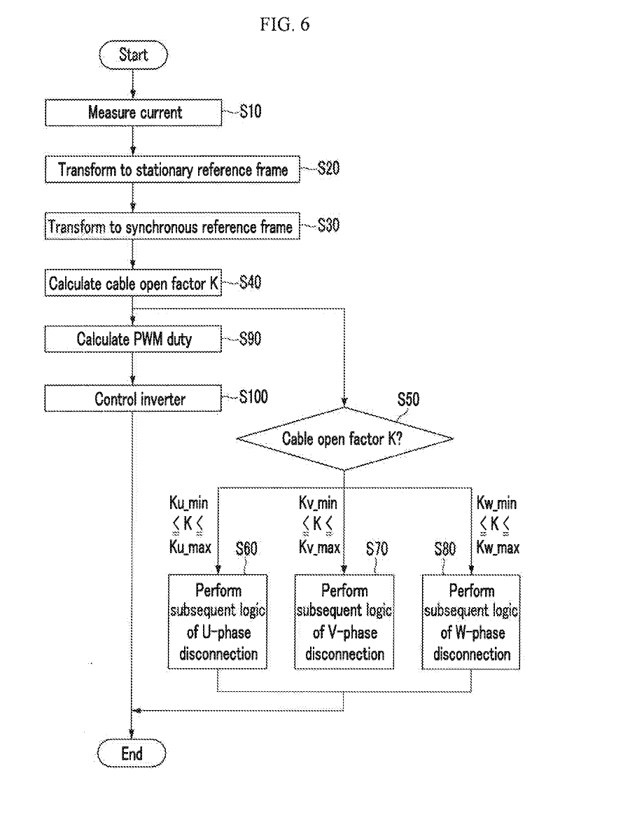

Moreover, in the motor control method of FIG. 1, the detecting of the disconnection of the power cable (S50) before the calculating of the PWM duty (S90) is described as an example. However, the present invention is not limited thereto. In other words, the detection of the disconnection according to the present exemplary embodiment is based on the three-phase currents Iu, Iv, and Iw which are coordinate-transformed to the stationary reference frame. Accordingly, the disconnection of the power cable may be detected before occurrence of the coordinate transformation of the current at a next cycle after the coordinate transformation of the three-phase currents Iu, Iv, and Iw. Accordingly, as illustrated in FIG. 5, the detecting of the disconnection of the power cable according to the present exemplary embodiment (S50) may be performed in parallel (e.g., simultaneously) with the calculating of the PWM duty (S90). Otherwise, as illustrated in FIG. 6, the detecting of the disconnection of the power cable according to the present exemplary embodiment (S50) may be performed in parallel with the calculating of the PWM duty (S90) and the operation of the inverter based on the calculating of the PWM duty (S100). Further, the detecting of the disconnection of the power cable (S50) may be performed after the transformed u-phase current Iu, v-phase current Iv, and w-phase current Iw are transformed to the synchronous reference frame (S30) in FIG. 1, but may be performed after the u-phase current Iu, the v-phase current Iv, and the w-phase current Iw are transformed to the stationary reference frame (S20) and before the transformed u-phase current Iu, v-phase current Iv, and w-phase current Iw are transformed to the synchronous reference frame (S30).

Further, in the aforementioned exemplary embodiment, the calculating of the cable open factor K using the current of the stationary reference frame transformed from the three-phase currents without change to operate the motor is described as an example in the motor control method. However, the present invention is not limited thereto. Accordingly, as illustrated in FIG. 5, the coordinates of the current may be transformed to the stationary reference frame (S20), and then the cable open factor K may be calculated using a current obtained by low pass filtering the transformed current (S30). When the cable open factor K calculated using the low pass filtered current is used, it may be possible to improve accuracy of the calculation of the cable open factor K, and improve accuracy of the detection of the disconnection of the cable as a result.

The characteristic, the structure, the effect, and the like according to the above description are included in at least one exemplary embodiment of the present invention, and are not essentially limited to one exemplary embodiment. Further, the characteristic, the structure, and the effect, and the like exemplified in each exemplary embodiment may be implemented through combination or modification for other exemplary embodiments by one skilled in the art to which the exemplary embodiments of the present invention pertains. Accordingly, it shall be construed that the contents related to the combination and the modification are included in the scope of the present invention.

What is claimed is:

1. A method of detecting disconnection of a motor power cable, comprising:
measuring, by a controller, a plurality of phase currents supplied to a motor via a power cable from an inverter;
transforming, by the controller, the plurality of phase currents to a stationary reference frame to obtain a first axis current of the synchronous reference frame and a second axis current of the synchronous reference frame;
calculating, by the controller, a cable open factor using the first axis current of the stationary reference frame and the second axis current of the stationary reference frame; and
detecting, by the controller, a disconnection of the power cable by the cable open factor.

2. The method of claim 1, wherein the cable open factor is defined by:
$$K = \frac{Idss}{Iqss}$$
wherein, K is the cable open factor, Idss is the first axis current of the stationary reference frame, and Iqss is the second axis current of the stationary reference frame.

3. The method of claim 2, wherein:
the power cable includes a first power cable, a second power cable, and a third power cable, and
when the cable open factor is included in an open factor range of the first power cable, disconnection of the first power cable is detected,
when the cable open factor is included in an open factor range of the second power cable, disconnection of the second power cable is detected, and
when the cable open factor is included in an open factor range of the third power cable, disconnection of the third power cable is detected.

4. A method of controlling a motor, comprising:
measuring, by a controller, a plurality of phase currents supplied to a motor via a power cable from an inverter;
transforming, by the controller, a plurality of phase currents to a stationary reference frame;
transforming, by the controller, the transformed currents to a synchronous reference frame;
detecting, by the controller, disconnection of the power cable;
calculating, by the controller, a pulse width modulation (PWM) duty using the current of the synchronous reference frame; and
operating, by the controller, the inverter based on the PWM duty,
wherein when the phase current is transformed to the stationary reference frame, the first axis current of the stationary reference frame and the second axis current of the stationary reference frame are generated, and
when the disconnection of the power cable is detected, a cable open factor is calculated using the first axis current of the stationary reference frame and the second axis current of the stationary reference frame, and the disconnection of the power cable is detected using the cable open factor.

5. The method of claim 4, wherein the cable open factor is defined by:
$$K = \frac{Idss}{Iqss}$$
wherein, K is the cable open factor, Idss is the first axis current of the stationary reference frame, and Iqss is the second axis current of the stationary reference frame.

6. The method of claim 5, wherein:
the power cable includes a first power cable, a second power cable, and a third power cable, and
when the cable open factor is included in an open factor range of the first power cable, disconnection of the first power cable is detected,
when the cable open factor is included in an open factor range of the second power cable, disconnection of the second power cable is detected, and
when the cable open factor is included in an open factor range of the third power cable, detection of the third power cable is detected.

7. The method of claim 4, wherein:
the detecting of the disconnection of the power cable is performed before the calculating of the PWM duty, or
the detecting of the disconnection of the power cable is performed in parallel with at least one of the calculating of the PWM duty and the operating of the inverter.

8. The method of claim 4, wherein:
after the detecting of the disconnection of the power cable, a subsequent logic necessary after the disconnection is performed.

9. A system for detecting disconnection of a power cable of a motor, comprising:
a controller configured to:
measure a plurality of phase currents supplied to a motor via a power cable from an inverter;
transform the plurality of phase currents to a stationary reference frame to obtain a first axis current of the synchronous reference frame and a second axis current of the synchronous reference frame;
calculate a cable open factor using the first axis current of the stationary reference frame and the second axis current of the stationary reference frame; and
detect a disconnection of the power cable by the cable open factor.

10. The system of claim 9, wherein the cable open factor is defined by:
$$K = \frac{Idss}{Iqss}$$
wherein, K is the cable open factor, Idss is the first axis current of the stationary reference frame, and Iqss is the second axis current of the stationary reference frame.

11. The system of claim 2, wherein:
the power cable includes a first power cable, a second power cable, and a third power cable, and
when the cable open factor is included in an open factor range of the first power cable, disconnection of the first power cable is detected,
when the cable open factor is included in an open factor range of the second power cable, disconnection of the second power cable is detected, and
when the cable open factor is included in an open factor range of the third power cable, disconnection of the third power cable is detected.

12. A non-transitory computer readable medium containing program instructions executed by a processor or controller, the computer readable medium comprising:
program instructions that measure a plurality of phase currents supplied to a motor via a power cable from an inverter;
program instructions that transform a plurality of phase currents to a stationary reference frame;
program instructions that transform the transformed currents to a synchronous reference frame;
program instructions that detect disconnection of the power cable;
program instructions that calculate a pulse width modulation (PWM) duty using the current of the synchronous reference frame; and
program instructions that operate the inverter based on the PWM duty,
wherein when the phase current is transformed to the stationary reference frame, the first axis current of the stationary reference frame and the second axis current of the stationary reference frame are generated, and
when the disconnection of the power cable is detected, a cable open factor is calculated using the first axis current of the stationary reference frame and the second axis current of the stationary reference frame, and the disconnection of the power cable is detected using the cable open factor.

13. The non-transitory computer readable medium of claim 12, wherein the cable open factor is defined by:
$$K = \frac{Idss}{Iqss}$$
wherein, K is the cable open factor, Idss is the first axis current of the stationary reference frame, and Iqss is the second axis current of the stationary reference frame.

14. The non-transitory computer readable medium of claim 13, wherein:
the power cable includes a first power cable, a second power cable, and a third power cable, and
when the cable open factor is included in an open factor range of the first power cable, disconnection of the first power cable is detected,
when the cable open factor is included in an open factor range of the second power cable, disconnection of the second power cable is detected, and
when the cable open factor is included in an open factor range of the third power cable, detection of the third power cable is detected.

15. The non-transitory computer readable medium of claim 12, wherein:
the detecting of the disconnection of the power cable is performed before the calculating of the PWM duty, or
the detecting of the disconnection of the power cable is performed in parallel with at least one of the calculating of the PWM duty and the operating of the inverter.

16. The non-transitory computer readable medium of claim 12, wherein:
after the detecting of the disconnection of the power cable, a subsequent logic necessary after the disconnection is performed.
